(19) United States
(12) Patent Application Publication
(10) Pub. No.: US 2025/0393400 A1
(43) Pub. Date: Dec. 25, 2025

(54) DISPLAY SUBSTRATE AND PREPARATION METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Tingliang LIU, Beijing (CN); Xiangdan DONG, Beijing (CN); Wei ZHANG, Beijing (CN); Yu WANG, Beijing (CN)

(21) Appl. No.: 18/881,268

(22) PCT Filed: May 27, 2024
(86) PCT No.: PCT/CN2024/095425

§ 371 Date: Jan. 4, 2025

(30) Foreign Application Priority Data
Jun. 8, 2023 (CN) 202310678863.3

(51) Int. Cl. H10K 59/122; H10K 59/12

(52) U.S. Cl. CPC H10K 59/122; H10K 59/1201

(57) ABSTRACT

A display substrate and a preparation method therefor, and a display apparatus, relating to, but not limited to, the technical field of display. The display substrate comprises a base, and a pixel definition layer, an isolation structure and a support structure which are provided on one side of the base. The support structure is configured to support a mask, and the isolation structure is configured to disconnect at least part of an organic light-emitting layer, the support structure comprises a first support layer and a second support layer which are stacked; and the vertical distance from the surface of the side of the isolation structure close to the base to the surface of the base is L1, the vertical distance from the surface of the side of the second support layer close to the base to the surface of the base is L2, and L1 is less than L2.

### CROSS-REFERENCE TO RELATED APPLICATIONS

The present application is a U.S. National Phase Entry of International Application No. PCT/CN2024/095425 having an international filing date of May 27, 2024, which claims priority to Chinese Patent Application No. 202310678863.3, filed to the CNIPA on Jun. 8, 2023 and entitled “Display Substrate and Preparation Method therefor, and Display Apparatus”. The above-identified applications are incorporated into the present application by reference in their entireties.

### TECHNICAL FIELD

The present disclosure relates to, but is not limited to, the field of display technologies, and in particular to a display substrate, a preparation method therefor, and a display apparatus.

### BACKGROUND

An Organic Light Emitting Diode (OLED) and a Quantum-dot Light Emitting Diode (QLED) are active light-emitting display devices, which have advantages of self-illumination, a wide viewing angle, a high contrast ratio, low power consumption, an extremely high reaction speed, lightness and thinness, flexibility, and a low cost. With constant development of display technologies, a flexible display apparatus (Flexible Display) in which an OLED or a QLED is used as a light-emitting device and signal control is performed through a Thin Film Transistor (TFT) has become a mainstream product in the field of display at present.

The power consumption index of Active-matrix organic light-emitting diode (AMOLED) display has become a core competitiveness of products, and Tandem technology has become a key technology to reduce power consumption. Tandem light-emitting device involves a transition from a single light-emitting layer to double layers. This solution may significantly improve device efficiency and reduce current, thereby reducing power consumption.

A charge generation layer (CGL) will be added to the AMOLED display substrate to improve longitudinal charge conduction ability. The charge generation layer (CGL) will increase lateral conduction of charges, causing a problem of crosstalk. For example, when a pixel (such as G pixel) has a display signal, a transfer charge will be transmitted to its adjacent pixel, and nearby R/G/B pixels that do not emit light will be lit, resulting in a color shift and affecting display effect.

### SUMMARY

The following is a summary of subject matter described in the present disclosure in detail. This summary is not intended to limit the protection scope of claims.

An embodiment of the present disclosure provides a display substrate, including a base substrate, and a pixel definition layer, an isolation structure and a support structure that are provided on a side of the base substrate. The support structure is configured to support a mask, and the isolation structure is configured to block at least a portion of an organic light-emitting layer.

The support structure includes a first support layer and a second support layer that are stacked. The first support layer is located on a side of the second support layer close to the base substrate, a thickness of the first support layer is substantially the same as that of the pixel definition layer, and a vertical distance from a surface of the second support layer away from the base substrate to a surface of the base substrate is greater than a vertical distance from a surface of the isolation structure away from the base substrate to the surface of the base substrate.

A vertical distance from a surface of the isolation structure close to the base substrate to the surface of the base substrate is L1, a vertical distance from a surface of the second support layer close to the base substrate to the surface of the base substrate is L2, and L1 is less than L2.

In an exemplary embodiment, the first support layer and the second support layer are integrally connected.

In an exemplary embodiment, the support structure and the pixel definition layer are located in a same film layer and are made of a same material.

In an exemplary embodiment, the first support layer and the second support layer are located in different film layers.

In an exemplary embodiment, the first support layer and the pixel definition layer are located in a same film layer and are made of a same material.

In an exemplary embodiment, the second support layer and the isolation structure are located in a same film layer and are made of a same material.

In an exemplary embodiment, the second support layer and the isolation structure both have a shape that is larger on a side away from the base substrate and smaller on a side close to the base substrate in a cross section perpendicular to a direction of the base substrate.

In an exemplary embodiment, a difference between L2 and L1 is 0.8 micron to 1 micron.

In an exemplary embodiment, the display substrate further includes a dielectric layer provided between the isolation structure and the base substrate, and the dielectric layer is in contact with the isolation structure.

In an exemplary embodiment, the dielectric layer and the first support layer are both made of a positive optical adhesive, and the isolation structure and the second support layer are both made of a negative optical adhesive.

In an exemplary embodiment, the dielectric layer and the first support layer are integrally connected.

In an exemplary embodiment, the dielectric layer and the pixel definition layer are integrally connected.

In an exemplary embodiment, the organic light-emitting layer at least includes a charge generation layer, and the isolation structure is configured to block at least a portion of the charge generation layer.

In an exemplary embodiment, the display substrate further includes a plurality of light-emitting devices, a first interval is provided between at least partial adjacent light-emitting devices, and a part of isolation structures is provided in the first interval.

In an exemplary embodiment, the display substrate further includes a plurality of light-emitting devices, a second interval is provided between at least partial adjacent light-emitting devices, and a part of isolation structures and a part of support structures are both provided in the second interval.

In an exemplary embodiment, in the second interval, a minimum spacing between an edge of a bottom wall of the isolation structure and an edge of a bottom wall of the support structure adjacent thereto is 1.5 micron to 3 micron.

In an exemplary embodiment, in the second interval, a minimum spacing between an edge of a bottom wall of the isolation structure and an edge of a bottom wall of the pixel definition layer adjacent thereto is 2 micron to 2.5 micron.

In an exemplary embodiment, the isolation structure is an inverted trapezoid in the cross section perpendicular to the direction of the base substrate, and a slope angle of a side wall of the isolation structure is 60 degrees to 80 degrees.

In an exemplary embodiment, the isolation structure has a thickness of 1.2 micron to 2 micron.

An embodiment of the present disclosure further provides a display apparatus, including any one of the display substrates described above.

An embodiment of the present disclosure further provides a preparation method for a display substrate, including forming a pixel definition layer, a support structure, and an isolation structure on a base substrate.

The support structure is configured to support a mask, and the isolation structure is configured to block at least a portion of an organic light-emitting layer. The support structure includes a first support layer and a second support layer that are stacked. The first support layer is located on a side of the second support layer close to the base substrate, and a thickness of the first support layer is substantially the same as that of the pixel definition layer.

A vertical distance from a surface of the isolation structure close to the base substrate to a surface of the base substrate is less than a vertical distance from a surface of the second support layer close to the base substrate to the surface of the base substrate.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and do not constitute a limitation on the technical solutions of the present application.

FIG. 1 is a schematic diagram of a structure of a display apparatus.

FIG. 2 is a schematic diagram of a planar structure of a display substrate.

FIG. 3 is a schematic diagram of a cross-sectional structure of a display substrate.

FIG. 4 is a schematic diagram of a cross-sectional structure of a display substrate in related art.

FIG. 5 is a schematic diagram of a cross-sectional structure of a display substrate according to an exemplary embodiment of the present disclosure.

FIG. 6 is an enlarged view of the pixel definition layer and the isolation structure of FIG. 5.

FIG. 7a is a schematic diagram of a display substrate after an insulating thin film is formed according to an exemplary embodiment of the present disclosure.

FIG. 7b is a schematic diagram of a display substrate after a pixel definition layer and a support structure are formed according to an embodiment of the present disclosure.

FIG. 8 is a schematic diagram of a cross-sectional structure of another display substrate according to an exemplary embodiment of the present disclosure.

FIG. 9 is a schematic diagram of a cross-sectional structure of yet another display substrate according to an exemplary embodiment of the present disclosure.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the accompanying drawings, a size of each composition element, a thickness of a layer, or a region may be exaggerated sometimes for clarity. Therefore, an implementation of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first pole may be a drain electrode, and a second pole may be a source electrode. Or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within process and measurement error ranges are allowed.

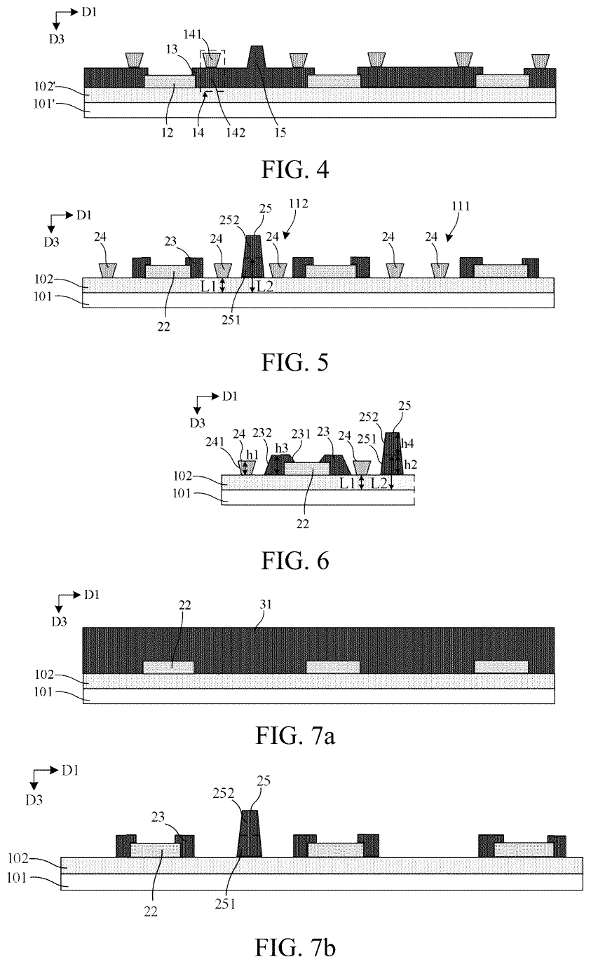

Through research by the inventors of the present disclosure, as shown in FIG. 4, a display substrate in related art includes a base substrate 101′, a drive circuit layer 102′ provided on a side of the base substrate 101′, a first electrode 12 provided on a side of the drive circuit layer 102′ away from the base substrate 101′, an organic light-emitting layer (not shown in the figure), a pixel definition layer 13, an isolation structure 14, and a support structure 15. The pixel definition layer 13 is provided with a pixel opening, the pixel opening exposes at least a portion of a surface of the first electrode 12, and an organic light-emitting layer is provided in the pixel opening and connected to the first electrode 12. Both the isolation structure 14 and the support structure 15 are located on a side of the pixel definition layer 13 in a first direction D1. The isolation structure 14 is configured to block a portion of the film layer (for example, a charge generation layer) in the organic light-emitting layer, to disconnect organic light-emitting layers of adjacent sub-pixels from each other, thereby avoiding lateral conduction of charges, and solving a problem of charge crosstalk. The support structure 15 is configured to support a mask that may be used to form a subsequent film layer, for example, vapor deposition of the organic light-emitting layer. The first direction D1 is parallel to the base substrate 101.

As shown in FIG. 4, the isolation structure 14 generally employs a stacked structure composed of an inorganic layer 141 and a negative optical adhesive layer 142 (negative PS adhesive layer). The negative optical adhesive layer 142 is located on a side of the inorganic layer 141 away from the base substrate. The negative optical adhesive layer 142 has an inverted trapezoidal shape in a cross section perpendicular to a direction of the base substrate, to block the organic light-emitting layer. The inorganic layer 141 is generally prepared and formed by a same process using a same material as the pixel definition layer 13, and a thickness of the inorganic layer 141 is substantially the same as that of the pixel definition layer 13. The support structure 15 may made of an inorganic material. A thickness of the isolation structure 14 is typically 1.2 micron to 1.4 micron, and a thickness of the support structure 15 is typically 1.6 micron to 1.8 micron.

A preparation process of a display substrate in related art includes: first preparing and forming an inorganic thin film; then forming the inorganic thin film into a pixel definition layer 13, an inorganic layer 141, and a support structure 15 by using a patterning process, thicknesses of the pixel definition layer 13 and the inorganic layer 141 being substantially the same and both being smaller than a thickness of the support structure 15, for example, the thicknesses of the pixel definition layer 13 and the inorganic layer 141 being 0.8 micron to 1.0 micron, and the thickness of the support structure 15 being 1.6 micron to 1.8 micron; and subsequently forming, on the inorganic layer 141, a negative optical adhesive layer 142 that has an inverted trapezoidal shape. The negative optical adhesive layer 142 and the inorganic layer 141 form the isolation structure 14, and a thickness of the isolation structure 14 is 1.2 micron to 1.4 micron.

Due to the similar thickness of the support structure 15 and the isolation structure 14, when the support structure 15 supports the mask, accumulation of an evaporation material on the mask leads to an increase in weight of the mask, thereby increasing a sag amount of the mask. This causes the mask to rub against a film layer (such as the isolation structure 14) on the base substrate, causing a subsequently formed film layer to be stacked at a site where friction occurs. Consequently, a subsequently formed power supply signal line (for example, a VSS signal line) is broken at the stacked locations, resulting in a problem that the pixel does not emit light or is difficult to emit light (cross-voltage increases). Moreover, the negative optical adhesive layer 142 in the isolation structure 14 increases this risk. The negative optical adhesive layer 142 has an extremely high pixel ratio, which may greatly degrade the quality of the display substrate.

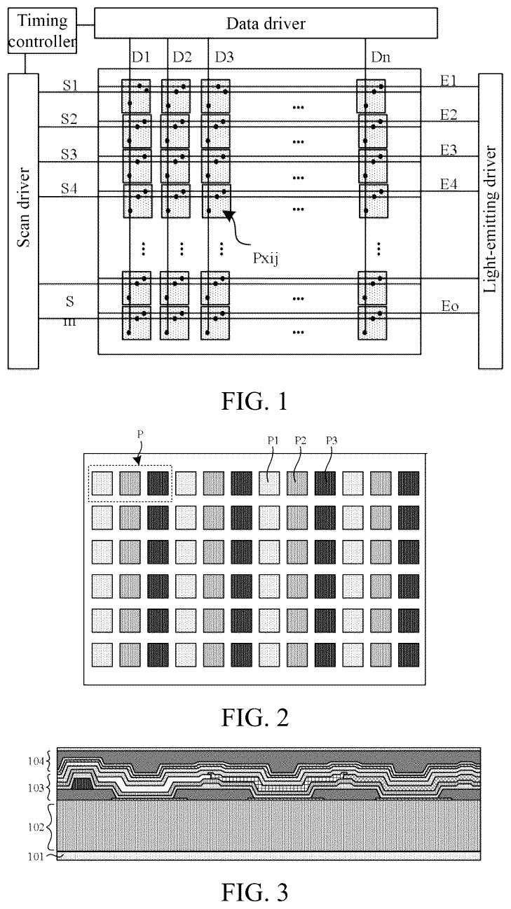

FIG. 1 is a schematic diagram of a structure of a display apparatus. As shown in FIG. 1, the display apparatus may include a timing controller, a data driver, a scan driver, a light-emitting driver, and a pixel array. The timing controller is connected to the data driver, the scan driver, and the light-emitting driver, respectively, the data driver is connected to a plurality of data signal lines (D1 to Dn) respectively, the scan driver is connected to a plurality of scan signal lines (S1 to Sm) respectively, and the light-emitting driver is connected to a plurality of light-emitting signal lines (E1 to Eo) respectively. The pixel array may include a plurality of sub-pixels Pxij, i and j may be natural numbers, at least one sub-pixel Pxij may include a circuit unit and a light-emitting unit, and the circuit unit may at least include a pixel drive circuit connected to a scan signal line, a light-emitting signal line and a data signal line, respectively. The light-emitting unit may include a light-emitting device connected to the pixel drive circuit of the circuit unit. In an exemplary embodiment, the timing controller may provide the data driver with a grayscale value and a control signal which are suitable for a specification of the data driver, provide the scan driver with a clock signal and a scan start signal and the like which are suitable for a specification of the scan driver, and provide the light-emitting driver with a clock signal and an emission stop signal and the like which are suitable for a specification of the light-emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light-emitting driver may receive a clock signal, an emission stop signal, etc., from the timing controller to generate an emission signal to be provided to the light-emitting signal lines E1, E2, E3, . . . , and Eo. For example, the light-emitting driver may sequentially provide an emission signal with an off-level pulse to the light-emitting signal lines E1 to Eo. For example, the light-emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary embodiment, the pixel array may be provided on a display substrate.

FIG. 2 is a schematic diagram of a planar structure of a display substrate. In an exemplary embodiment, the display substrate may include a display region and a bezel region located on a periphery of the display region. As shown in FIG. 2, the display region of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light-emitting unit. The circuit unit may at least include a pixel drive circuit, the pixel drive circuit is connected to a scan signal line, a data signal line, and a light-emitting signal line, respectively, and is configured to receive a data voltage transmitted by the data signal line and output a corresponding current to the light-emitting device under control of the scan signal line and the light-emitting signal line. The light-emitting unit may at least include a light-emitting device. The light-emitting device is connected to a pixel drive circuit of a sub-pixel where the light-emitting device is located. The light-emitting device is configured to emit light with a corresponding brightness in response to a current output by the pixel drive circuit of the sub-pixel where the light-emitting device is located.

In an exemplary embodiment, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary embodiment, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary embodiment, a pixel unit may include four sub-pixels, and the four sub-pixels may be arranged in a manner to stand side by side horizontally, in a manner to stand side by side vertically, or in a manner of forming a square, which is not limited here in the present disclosure.

FIG. 3 is a schematic diagram of a cross-sectional structure of a display substrate, which illustrates a structure of three sub-pixels of the display substrate. As shown in FIG. 3, in a plane perpendicular to the display substrate, a display region of the display substrate may include a drive circuit layer 102 provided on a base substrate 101, a light-emitting structure layer 103 provided on a side of the drive circuit layer 102 away from the base substrate 101, and an encapsulation structure layer 104 provided on a side of the light-emitting structure layer 103 away from the base substrate 101. In some possible implementation modes, the display substrate may include another film layer, such as a touch structure layer, which is not limited here in the present disclosure.

In an exemplary embodiment, the base substrate 101 may be a flexible base substrate, or may be a rigid base substrate. The drive circuit layer 102 may include a plurality of circuit units. A circuit unit may at least include a pixel drive circuit, and the pixel drive circuit may include a plurality of transistors and a storage capacitor. The light-emitting structure layer 103 may include a plurality of light-emitting units. A light-emitting unit may at least include a light-emitting device, and the light-emitting device may include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode. The encapsulation structure layer 104 may include a first encapsulation structure layer, a second encapsulation structure layer, and a third encapsulation structure layer that are stacked. The first encapsulation structure layer and the third encapsulation structure layer may be made of an inorganic material, the second encapsulation structure layer may be made of an organic material, and the second encapsulation structure layer is provided between the first encapsulation structure layer and the third encapsulation structure layer to form a stacked structure of inorganic material/organic material/inorganic material and ensure that external moisture cannot enter the light-emitting structure layer 103.

In an exemplary embodiment, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), an Electron Injection Layer (EIL) and a charge generation layer (CGL).

An exemplary embodiment of the present disclosure provides a display substrate, including a base substrate, and a pixel definition layer, an isolation structure and a support structure that are provided on a side of the base substrate. The support structure is configured to support a mask, and the isolation structure is configured to block at least a portion of an organic light-emitting layer.

The support structure includes a first support layer and a second support layer that are stacked. The first support layer is located on a side of the second support layer close to the base substrate, a thickness of the first support layer is substantially the same as that of the pixel definition layer, and a vertical distance from a surface of the second support layer away from the base substrate to a surface of the base substrate is greater than a vertical distance from a surface of the isolation structure away from the base substrate to the surface of the base substrate.

A vertical distance from a surface of the isolation structure close to the base substrate to the surface of the base substrate is L1, a vertical distance from a surface of the second support layer close to the base substrate to the surface of the base substrate is L2, and L1 is less than L2.

In an exemplary embodiment, there may be a certain error between the thicknesses of the first support layer and the pixel definition layer. For example, a ratio of the thickness of the first support layer to the thickness of the pixel definition layer may be 0.9 to 1.1, and a difference between the thickness of the first support layer and the thickness of the pixel definition layer may be 0.3 micron to-0.3 micron.

The solution of the present embodiment will be described below through some examples.

FIG. 5 is a schematic diagram of a cross-sectional structure of a display substrate according to an exemplary embodiment of the present disclosure. FIG. 5 illustrates a structure of three sub-pixels in the display substrate. In an exemplary embodiment, as shown in FIG. 5, on a plane perpendicular to the direction of the base substrate, the display substrate according to an exemplary embodiment of the present disclosure may include a base substrate 101, a drive circuit layer 102 provided on a side of the base substrate 101, and a light-emitting device, a pixel definition layer 23, an isolation structure 24, and a support structure 25 provided on a side of the drive circuit layer 102 away from the base substrate 101. The support structure 25 is configured to support a mask, and the isolation structure 24 is configured to block at least a portion of an organic light-emitting layer.

In an exemplary embodiment, the light-emitting device includes a first electrode 22, an organic light-emitting layer (not shown in the figure), and a second electrode (not shown in the figure) which are sequentially stacked in a thickness direction of the base substrate. The first electrode 22 may serve as an anode, and the second electrode may serve as a cathode. The first electrode 22 is electrically connected to the drive circuit layer 102, and the first electrode 22 of an adjacent sub-pixel is disconnected from each other. The second electrode is provided as an entire surface, and a plurality of sub-pixels may share one second electrode. The organic light-emitting layer at least includes a light-emitting layer, and organic light-emitting layers of adjacent sub-pixels are separated from each other by the isolation structure 24.

In an exemplary embodiment, the pixel definition layer 23 is provided on a side of the first electrode 22 away from the base substrate, a pixel opening is provided in the pixel definition layer 23, and the pixel opening exposes at least a portion of a surface of the first electrode 12. Pixel definition layers 23 of adjacent sub-pixels are arranged at intervals in a first direction D1, and the pixel definition layers 23 of the adjacent sub-pixels are disconnected from each other.

In an exemplary embodiment, the light-emitting device may be an organic light-emitting diode (Tandem OLED). An organic light-emitting layer of the light-emitting device is provided on a side of the pixel definition layer 23 away from the base substrate, and at least a portion of the organic light-emitting layer is provided in the pixel opening of the pixel definition layer 23 to be connected to the first electrode 22. The organic light-emitting layer may include at least two light-emitting layers stacked in a thickness direction of the base substrate and a charge generation layer (CGL) located between adjacent light-emitting layers. The charge generation layer (CGL) is used to improve conductivity of charges in the thickness direction of the base substrate.

In an exemplary embodiment, the isolation structure 24 is provided on a side of the drive circuit layer 102 away from the base substrate 101. In a direction parallel to the base substrate 101, the isolation structure 24 is located on a side of the pixel definition layer 23 away from the first electrode 22, and an orthographic projection of the isolation structure 24 on the base substrate 101 is not overlapped with orthographic projections of the pixel definition layer 23 and the first electrode 22 on the base substrate 101, respectively. A portion of a film layer (for example, the charge generation layer) of the organic light-emitting layer is blocked by the isolation structure 24, that is, a portion of a film layer (for example, the charge generation layer) of the organic light-emitting layer is broken at the isolation structure 24, so as to avoid lateral conduction of charges and solve a problem of charge crosstalk. For example, the isolation structure 24 blocks at least the charge generation layer of the organic light-emitting layer.

In an exemplary embodiment, in a direction parallel to the base substrate 101, the isolation structure 24 is annular, and the isolation structure 24 is provided around a periphery of the light-emitting device.

FIG. 6 is an enlarged view of the pixel definition layer and the isolation structure of FIG. 5. In an exemplary embodiment, as shown in FIGS. 5 and 6, a main body portion of the pixel definition layer 23 may be a regular trapezoid in a cross section perpendicular to the direction of the base substrate. The pixel definition layer 23 includes an inner side surface 231 and an outer side surface 232 provided opposite each other in the first direction D1, and the inner side surface 231 is located on a side of the outer side surface 232 close to the first electrode 22. Slope angles formed by a plane on which the base substrate 101 is located and the inner side surface 231 and the outer side surface 232 are both acute angles. A portion of a film layer (for example, the charge generation layer) of the organic light-emitting layer climbs at the inner side surface 231 and the outer side surface 232, and does not break.

In an exemplary embodiment, the pixel definition layer 23 has a single-film layer structure, and the pixel definition layer 23 may be made of a positive optical adhesive.

In an exemplary embodiment, in a cross section perpendicular to the direction of the base substrate, the isolation structure 24 may have a cylindrical shape. The isolation structure 24 may have a shape that is larger on a side away from the base substrate and smaller on a side close to the base substrate. For example, the isolation structure 24 may be an inverted trapezoid, and a slope angle of a side wall 241 of the isolation structure 24 is 60 degrees to 80 degrees. The isolation structure 24 includes a side wall 241, and a slope angle formed by the side wall 241 and a plane on which the base substrate 101 is located is an obtuse angle. A portion of a film layer (for example, the charge generation layer) of the organic light-emitting layer is blocked at the isolation structure 24, so as to avoid lateral conduction of charges along the organic light-emitting layer and solve a problem of charge crosstalk.

In an exemplary embodiment, the isolation structure 24 further includes a bottom wall. A length of the bottom wall of the isolation structure 24 in the first direction D1 is greater than 0.6 micron. A thickness hl of the isolation structure 24 is 1.2 micron to 2 micron. The bottom wall refers to a surface on a side close to the base substrate.

In an exemplary embodiment, the isolation structure 24 is a single-film layer structure, and the isolation structure 24 may be made of a negative optical adhesive.

In an exemplary embodiment, as shown in FIGS. 5 and 6, the support structure 25 is provided on a side of the drive circuit layer 102 away from the base substrate 101, the support structure 25 is located between adjacent pixel definition layers 23, and an orthographic projection of the support structure 25 on the base substrate 101 is not overlapped with orthographic projections of the isolation structure 24, the pixel definition layer 23, and the first electrode 22 on the base substrate 101, respectively. The support structure 25 serves to support a mask that may be used for subsequent formation of the organic light-emitting layer.

In an exemplary embodiment, the support structure 25 includes a first support layer 251 and a second support layer 252 that are sequentially stacked in the thickness direction of the base substrate, and the first support layer 251 is located on a side of the second support layer 252 close to the base substrate. A thickness of the first support layer 251 is h2, a thickness of the pixel definition layer 23 is h3, and a thickness of the second support layer 252 is h4. The thickness h2 of the first support layer 251 may be equal to the thickness h3 of the pixel definition layer 23, a vertical distance from a surface of the second support layer 252 away from the base substrate to a surface of the base substrate 101 is greater than a vertical distance from a surface of the pixel definition layer 23 away from the base substrate to the surface of the base substrate 101, and the vertical distance from the surface of the second support layer 252 away from the base substrate to the surface of the base substrate 101 is greater than a vertical distance from a surface of the isolation structure 24 away from the base substrate to the surface of the base substrate 101. A sum of the thickness h2 of the first support layer 251 and the thickness h4 of the second support layer 252 is greater than the thickness h1 of the isolation structure 24, and a sum of the thickness h2 of the first support layer 251 and the thickness h4 of the second support layer 252 is greater than the thickness h3 of the pixel definition layer 23. Here, the surface of the base substrate 101 refers to a surface of the base substrate 101 on a side close to the drive circuit layer 102.

In an exemplary embodiment, a vertical distance from a surface of the isolation structure 24 close to the base substrate to the surface of the base substrate is L1, and a vertical distance from a surface of the second support layer 252 close to the base substrate to the surface of the base substrate is L2, and L1 is less than L2.

In an exemplary embodiment, a difference between L2 and L1 is equal to the thickness h2 of the first support layer.

In an exemplary embodiment, the difference between L2 and L1 is 0.8 micron to 1 micron.

According to the display substrate of the embodiments of the present disclosure, by making the vertical distance L1 from the surface of the isolation structure 24 close to the base substrate to the surface of the base substrate less than the vertical distance L2 between the surface of the second support layer 252 close to the base substrate to the surface of the substrate, a height difference between the isolation structure 24 and the support structure 25 is increased, and the mask and the isolation structure 24 are avoided to friction, thereby making the subsequently formed film layer gentle, ensuring that the power signal line is continuous without breaking, and improving the yield.

In an exemplary embodiment, the first support layer 251 and the second support layer 252 of the support structure 25 may be integrally connected. The first support layer 251 and the second support layer 252 are combined to form the support structure 25 having a regular trapezoidal shape in a cross section perpendicular to the direction of the base substrate.

In some embodiments, the first support layer 251 and the second support layer 252 are located on different film layers. The fact that the first support layer 251 and the second support layer 252 are located in different film layers means that the first support layer 251 and the second support layer 252 may be prepared separately by two patterning processes using different materials.

In an exemplary embodiment, the support structure 25 and the pixel definition layer 23 may be located in a same film layer, thereby simplifying the process and reducing the cost. The fact that the support structure 25 and the pixel definition layer 23 are located in the same film layer means that the support structure 25 and the pixel definition layer 23 may be prepared by a same patterning process using a same material.

In an exemplary embodiment, the support structure 25 is a single-film layer structure, and the support structure 25 may be made of a positive optical adhesive.

In an exemplary embodiment, a first interval 111 is provided between at least partial adjacent light-emitting devices, and a part of the isolation structures 24 is provided in the first interval 111. The support structure 25 is not provided in the first interval 111. That is, in the first interval 111, only a part of the isolation structures 24 is provided, and the support structure 25 is not provided.

In an exemplary embodiment, a second interval 112 is provided between at least partial adjacent light-emitting devices, and a part of the isolation structures 24 and a part of the support structures 25 are provided in the second interval 112. That is, in the second interval 112, a part of the isolation structures 24 and a part of the support structures 25 are respectively provided, and orthographic projections of the isolation structures 24 and the support structures 25 on the base substrate are not overlapped.

In an exemplary embodiment, in the second interval 112, a minimum spacing between an edge of a bottom wall of the isolation structure 24 and an edge of a bottom wall of the support structure 25 adjacent thereto is 1.5 micron to 3 micron. For example, the minimum spacing between the edge of the bottom wall of the isolation structure 24 and the edge of the bottom wall of the support structure 25 is 2 micron to 2.5 micron.

In an exemplary embodiment, in the second interval 112, a minimum spacing between an edge of a bottom wall of the isolation structure 24 and an edge of a bottom wall of the pixel definition layer 23 adjacent thereto is 1.5 micron to 3 micron. For example, the minimum spacing between the edge of the bottom wall of the isolation structure 24 and the edge of the bottom wall of the pixel definition layer 23 is 2 micron to 2.5 micron.

Exemplary description is made below through a preparing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed by a patterning process in the entire preparing process, the “thin film” may also be called a “layer”. If the “thin film” needs to be processed by a patterning process in the entire preparing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

A preparation process of the display substrate according to the embodiments of the present disclosure includes following steps:
(1) Forming an insulating thin film.

The step of forming the insulating thin film includes: first forming a drive circuit layer 102 on a base substrate 101; then forming a first electrode 22 on the drive circuit layer 102; and subsequently depositing, on the base substrate 101, an insulating thin film 31 that covers the first electrode 22, as shown in FIG. 7a.
(2) Forming a pixel definition layer and a support structure.

The step of forming the pixel definition layer and the support structure includes: forming, by a patterning process, the insulating thin film into a pixel definition layer 23 and a support structure 25 respectively on the base substrate on which the aforementioned pattern is formed, orthographic projections of the pixel definition layer 23 and the support structure 25 on the base substrate being not overlapped, as shown in FIG. 7b. A pixel opening is provided in the pixel definition layer 23, and the pixel opening exposes at least a portion of a surface of the first electrode 12. A thickness of the support structure 25 is greater than a thickness of the pixel definition layer 23, and a distance from a surface of the support structure 25 away from the base substrate to a surface of the base substrate 101 is greater than a distance from a surface of the pixel definition layer 23 away from the base substrate to the surface of the base substrate 101.
(3) Forming an isolation structure.

The step of forming the isolation structure includes: forming an isolation structure 24 on the drive circuit layer 102 on the base substrate on which the aforementioned patterns are formed, the isolation structure 24 being located between adjacent pixel definition layers 23, and an orthographic projection of the isolation structure 24 on the base substrate 101 being not overlapped with orthographic projections of the pixel definition layer 23, the first electrode 22, and the support structure 25 on the base substrate 101, respectively, as shown in FIG. 5.

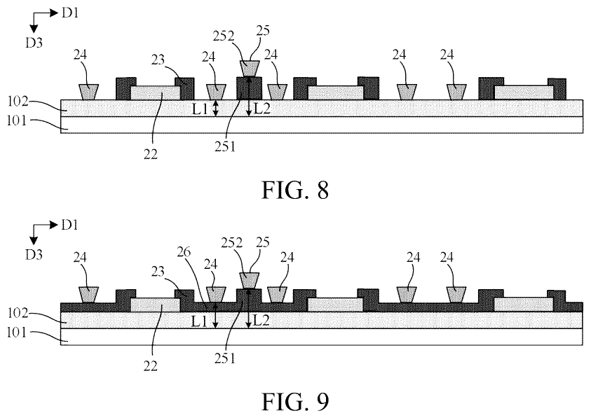

FIG. 8 is a schematic sectional view of a structure of another display substrate according to an exemplary embodiment of the present disclosure. As shown in FIG. 8, a structure of the display substrate in the present exemplary embodiment is basically the same as that of the embodiment shown in FIG. 5, except that the first support layer 251 and the second support layer 252 of the support structure 25 are located in different film layers. The fact that the first support layer 251 and the second support layer 252 are located in different film layers means that the first support layer 251 and the second support layer 252 are separately prepared by two patterning processes using different materials. A difference between a vertical distance L1 from a surface of the isolation structure 24 close to the base substrate to a surface of the base substrate and a vertical distance L2 from a surface of the second support layer 252 close to the base substrate to the surface of the base substrate is a thickness of the first support layer 251.

In an exemplary embodiment, the first support layer 251 and the pixel definition layer 23 may be located in a same film layer. The fact that the first support layer 251 and the pixel definition layer 23 are located in the same film layer means that the first support layer 251 and the pixel definition layer 23 are prepared by a same patterning process using a same material. For example, both the first support layer 251 and the pixel definition layer 23 are made of a positive optical adhesive.

In an exemplary embodiment, the second support layer 252 and the isolation structure 24 may be located on a same film layer. The fact that the second support layer 252 and the isolation structure 24 are located in the same film layer means that the second support layer 252 and the isolation structure 24 are prepared by a same patterning process using a same material. For example, both the second support layer 252 and the isolation structure 24 are made of a negative optical adhesive.

In an exemplary embodiment, in a cross section perpendicular to a direction of the base substrate, the second support layer 252 has a shape that is larger on a side away from the base substrate and smaller on a side close to the base substrate. For example, the second support layer 252 may be an inverted trapezoid.

In an exemplary embodiment, in a cross section perpendicular to a direction of the base substrate, the isolation structure 24 has a shape that is larger on a side away from the base substrate and smaller on a side close to the base substrate. For example, the isolation structure 24 may be an inverted trapezoid.

In an exemplary embodiment, the display substrate of the embodiment of the present disclosure further includes a color film structure layer provided on a side of the light-emitting device away from the base substrate. The color film structure layer includes a filter layer and a photoresist layer, and the photoresist layer is located around the filter layer. The pixel definition layer 23 of the display substrate of the embodiment of the present disclosure may be made of a photoresist material, such as a black photosensitive adhesive, and the pixel definition layer 23 may serves as a photoresist layer in the color film structure layer, thereby simplifying the process and reducing the cost.

FIG. 9 is a schematic diagram of a cross-sectional structure of yet another display substrate according to an exemplary embodiment of the present disclosure. As shown in FIG. 9, a structure of the display substrate in the present exemplary embodiment is basically the same as that of the embodiment shown in FIG. 8, except that the display substrate of the present exemplary embodiment further includes a dielectric layer 26 provided on a side of the isolation structure 24 close to the drive circuit layer 102, that is, the dielectric layer 26 is stacked between the isolation structure 24 and the drive circuit layer 102, and a surface of the isolation structure 24 close to the base substrate is in contact with the dielectric layer 26. A thickness of the dielectric layer 26 is less than a thickness of the first support layer 251 of the support structure 25. A difference between a vertical distance L1 from a surface of the isolation structure 24 close to the base substrate to a surface of the base substrate and a vertical distance L2 from a surface of the second support layer 252 close to the base substrate to the surface of the base substrate is less than a thickness of the first support layer 251.

In an exemplary embodiment, the dielectric layer 26 may be integrally connected to the first support layer 251 of the support structure 25 and the pixel definition layer 23, respectively. “Being integrally connected” means that the dielectric layer 26, the first support layer 251, and the pixel definition layer 23 are prepared by a same patterning process using a same material and formed into an integrated film layer; or the dielectric layer 26, the first support layer 251, and the pixel definition layer 23 are prepared separately by different patterning processes using different materials and then are connected to form an integrated film layer.

In an exemplary embodiment, the dielectric layer 26, the first support layer 251, and the pixel definition layer 23 are all made of a positive optical adhesive, and the isolation structure 24 and the second support layer 252 are both made of a negative optical adhesive.

The present disclosure further provides a preparation method for a display substrate, for preparing the display substrate according to the foregoing embodiments.

In an exemplary embodiment, the preparation method for the display substrate may include forming a pixel definition layer, a support structure, and an isolation structure on a base substrate.

The support structure is configured to support a mask, and the isolation structure is configured to block at least a portion of an organic light-emitting layer. The support structure includes a first support layer and a second support layer that are stacked. The first support layer is located on a side of the second support layer close to the base substrate, and a thickness of the first support layer is substantially the same as that of the pixel definition layer.

A vertical distance from a surface of the isolation structure close to the base substrate to a surface of the base substrate is less than a vertical distance from a surface of the second support layer close to the base substrate to the surface of the base substrate.

An embodiment of the present disclosure further provides a display apparatus, including any one of the display substrates described above. The display apparatus includes a mobile phone, a tablet computer, a wearable smart product (such as a smart watch, a bracelet, or the like), a personal digital assistant (PDA), a vehicle-mounted computer, or the like. A specific form of the above foldable display apparatus is not specially limited in the embodiments of the present application.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising a base substrate, and a pixel definition layer, an isolation structure and a support structure that are provided on a side of the base substrate, wherein the support structure is configured to support a mask, and the isolation structure is configured to block at least a portion of an organic light-emitting layer;
the support structure comprises a first support layer and a second support layer that are stacked, the first support layer is located on a side of the second support layer close to the base substrate, a thickness of the first support layer is substantially the same as that of the pixel definition layer, and a vertical distance from a surface of the second support layer away from the base substrate to a surface of the base substrate is greater than a vertical distance from a surface of the isolation structure away from the base substrate to the surface of the base substrate; and
a vertical distance from a surface of the isolation structure close to the base substrate to the surface of the base substrate is L1, a vertical distance from a surface of the second support layer close to the base substrate to the surface of the base substrate is L2, and L1 is less than L2.

2. The display substrate according to claim 1, wherein the first support layer and the second support layer are integrally connected.

3. The display substrate according to claim 2, wherein the support structure and the pixel definition layer are located in a same film layer and are made of a same material.

4. The display substrate according to claim 1, wherein the first support layer and the second support layer are located in different film layers.

5. The display substrate according to claim 4, wherein the first support layer and the pixel definition layer are located in a same film layer and are made of a same material.

6. The display substrate according to claim 4, wherein the second support layer and the isolation structure are located on a same film layer and are made of a same material.

7. The display substrate according to claim 6, wherein the second support layer and the isolation structure both have a shape that is larger on a side away from the base substrate and smaller on a side close to the base substrate in a cross section perpendicular to a direction of the base substrate.

8. The display substrate according to claim 1, wherein a difference between L2 and L1 is 0.8 micron to 1 micron.

9. The display substrate according to claim 1, further comprising a dielectric layer provided between the isolation structure and the base substrate, wherein the dielectric layer is in contact with the isolation structure.

10. The display substrate according to claim 9, wherein the dielectric layer and the first support layer are both made of a positive optical adhesive, and the isolation structure and the second support layer are both made of a negative optical adhesive.

11. The display substrate according to claim 9, wherein the dielectric layer and the first support layer are integrally connected.

12. The display substrate according to claim 9, wherein the dielectric layer and the pixel definition layer are integrally connected.

13. The display substrate according to claim 1, wherein the organic light-emitting layer at least comprises a charge generation layer, and the isolation structure is configured to block at least a portion of the charge generation layer.

14. The display substrate according to claim 1, further comprising a plurality of light-emitting devices, wherein a first interval is provided between at least partial adjacent light-emitting devices, and a part of isolation structures is provided in the first interval.

15. The display substrate according to claim 1, further comprising a plurality of light-emitting devices, wherein a second interval is provided between at least partial adjacent light-emitting devices, and a part of isolation structures and a part of support structures are both provided in the second interval.

16. The display substrate according to claim 15, wherein in the second interval, a minimum spacing between an edge of a bottom wall of the isolation structure and an edge of a bottom wall of the support structure adjacent to the isolation structure is 1.5 micron to 3 micron.

17. The display substrate according to claim 15, wherein in the second interval, a minimum spacing between an edge of a bottom wall of the isolation structure and an edge of a bottom wall of the pixel definition layer adjacent to the isolation structure is 2 micron to 2.5 micron.

18. The display substrate according to claim 1, wherein the isolation structure is of an inverted trapezoid in a cross section perpendicular to a direction of the base substrate, and a slope angle of a side wall of the isolation structure is 60 degrees to 80 degrees, and a thickness of the isolation structure is 1.2 micron to 2 micron.

19. (canceled)

20. A display apparatus, comprising the display substrate according to claim 1.

21. A preparation method for a display substrate, comprising:
forming a pixel definition layer, a support structure, and an isolation structure on a base substrate;
wherein the support structure is configured to support a mask, the isolation structure is configured to block at least a portion of an organic light-emitting layer, the support structure comprises a first support layer and a second support layer that are stacked, the first support layer is located on a side of the second support layer close to the base substrate, and a thickness of the first support layer is substantially the same as that of the pixel definition layer; and
a vertical distance from a surface of the isolation structure close to the base substrate to a surface of the base substrate is less than a vertical distance from a surface of the second support layer close to the base substrate to the surface of the base substrate.
